(19) United States
(12) Patent Application Publication
(10) Pub. No.: US 2025/0098298 A1
(43) Pub. Date: Mar. 20, 2025

(54) SEMICONDUCTOR DEVICE

(71) Applicant: KABUSHIKI KAISHA TOSHIBA, Tokyo (JP)

(72) Inventors: Tomoaki INOKUCHI, Yokohama (JP); Hiro GANGI, Tokyo (JP); Yusuke KOBAYASHI, Yokohama (JP); Tatsunori SAKANO, Tokyo (JP); Tatsuo SHIMIZU, Tokyo (JP); Shotaro BABA, Kawasaki (JP); Taichi FUKUDA, Yokohama (JP)

(73) Assignee: KABUSHIKI KAISHA TOSHIBA, Tokyo (JP)

(21) Appl. No.: 18/591,188

(22) Filed: Feb. 29, 2024

(30) Foreign Application Priority Data
Sep. 15, 2023 (JP) 2023-150148

(51) Int. Cl. H01L 27/12; H01L 27/02; H01L 29/40; H01L 29/47; H01L 29/812

(52) U.S. Cl. CPC H10D 86/201; H10D 30/871; H10D 30/873; H10D 64/117; H10D 64/64; H10D 89/10

(57) ABSTRACT

The major element includes a first electrode, a second electrode, a first semiconductor layer located between the first electrode and the second electrode, the first semiconductor layer forming a first Schottky junction with the second electrode, and a first gate electrode facing the first Schottky junction. The control element includes a third electrode, a fourth electrode, a second semiconductor layer located between the third electrode and the fourth electrode, the second semiconductor layer forming a second Schottky junction with the fourth electrode, and a second gate electrode facing the second Schottky junction.

### CROSS-REFERENCE TO RELATED APPLICATION

This application is based upon and claims the benefit of priority from Japanese Patent Application No. 2023-150148, filed on Sep. 15, 2023; the entire contents of which are incorporated herein by reference.

### FIELD

Embodiments described herein relate generally to a semiconductor device.

### BACKGROUND

There is a need for a chip in which a control circuit is embedded in a power semiconductor device.

### BRIEF DESCRIPTION OF THE DRAWINGS

FIG. 1 is a schematic cross-sectional view of a semiconductor device of an embodiment;

FIGS. 2 and 3 are schematic perspective views of a major element of the semiconductor device of the embodiment;

FIG. 4 is a schematic cross-sectional view of the major element of the semiconductor device of the embodiment;

FIGS. 5A and 5B are schematic perspective views of the major element of the semiconductor device of the embodiment;

FIG. 6 is a schematic perspective view of a control element of the semiconductor device of the embodiment;

FIG. 7 is a schematic cross-sectional view of the control element of the semiconductor device of the embodiment;

FIG. 8A is a circuit diagram of a control circuit of the semiconductor device of the embodiment;

FIG. 8B is a schematic cross-sectional view of control elements forming the control circuit;

FIG. 9A is a circuit diagram of a control circuit of the semiconductor device of the embodiment;

FIG. 9B is a schematic cross-sectional view of control elements forming the control circuit;

FIG. 10A is a circuit diagram of a control circuit of the semiconductor device of the embodiment;

FIG. 10B is a schematic cross-sectional view of control elements forming the control circuit;

FIG. 11A is a circuit diagram of a control circuit of the semiconductor device of the embodiment; and

FIG. 11B is a schematic cross-sectional view of control elements forming the control circuit.

### DETAILED DESCRIPTION

According to one embodiment, a semiconductor device includes a support body including a first surface; a major element located on the support body; and a control element located on the support body, the control element controlling the major element, the major element including a first electrode, a second electrode positioned to be separated from the first electrode in a first direction, the first direction being along the first surface, a first semiconductor layer located between the first electrode and the second electrode in the first direction, the first semiconductor layer forming a first Schottky junction with the second electrode, and a first gate electrode facing the first Schottky junction in a second direction, the second direction being along the first surface and crossing the first direction, the control element including a third electrode, a fourth electrode positioned to be separated from the third electrode in a fourth direction, the fourth direction being along the first surface, a second semiconductor layer located between the third electrode and the fourth electrode in the fourth direction, the second semiconductor layer forming a second Schottky junction with the fourth electrode, and a second gate electrode facing the second Schottky junction in a fifth direction, the fifth direction being along the first surface and crossing the fourth direction.

Embodiments will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

The same or similar components are marked with the same reference numerals.

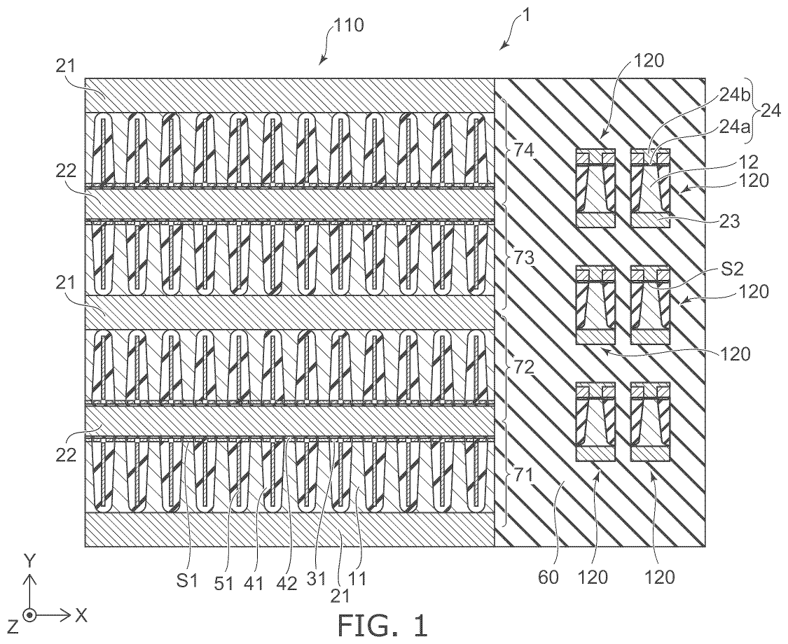

As shown in FIG. 1, a semiconductor device 1 of the embodiment includes a major element 110 and a control element 120. The major element 110 is a power semiconductor element that controls or converts power. The control element 120 controls the major element 110. For example, a control circuit that controls the major element 110 is formed of multiple control elements 120.

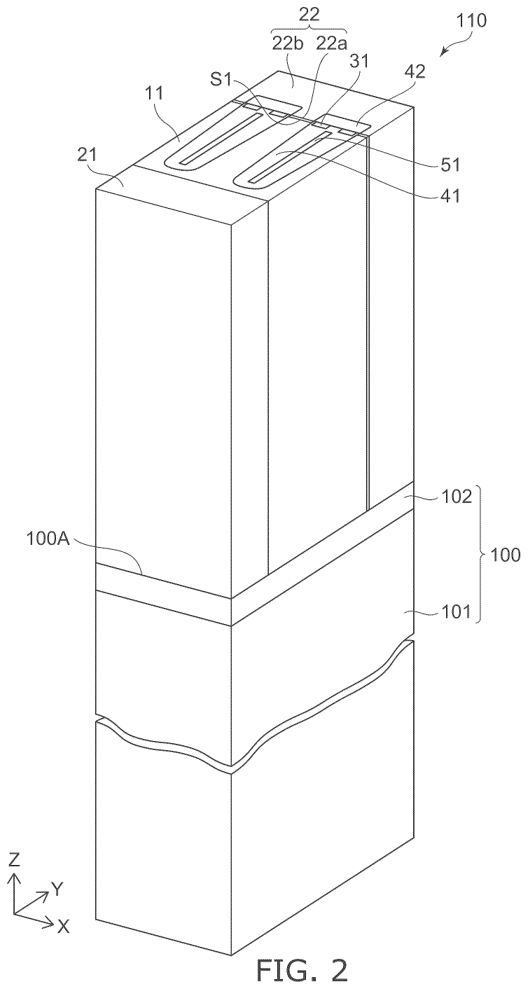

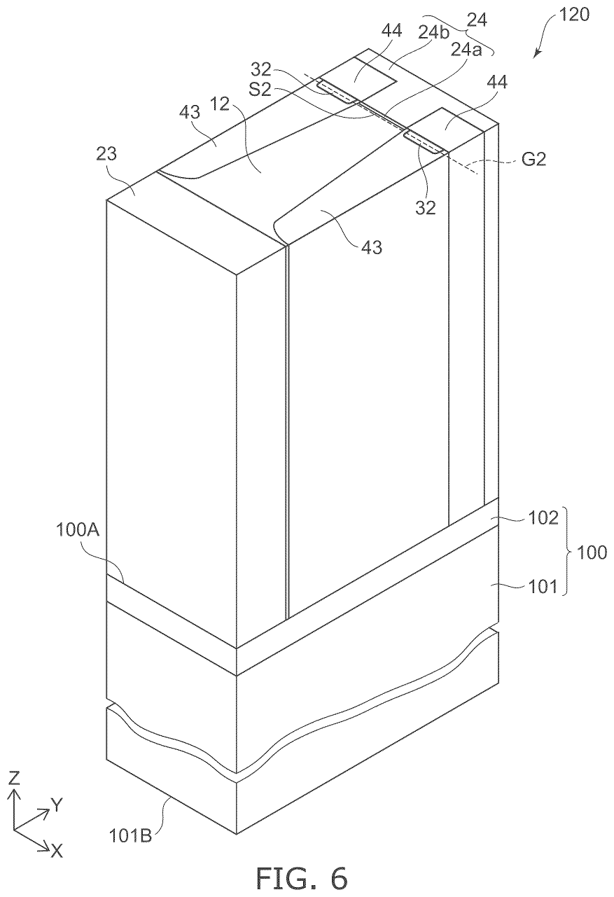

The semiconductor device 1 further includes a support body 100. As shown in FIG. 2, the major element 110 is located on the support body 100. As shown in FIG. 6, the control element 120 is located on the support body 100.

As shown in FIG. 2, the support body 100 includes a first surface 100A. One direction parallel to the first surface 100A is taken as an X-axis direction. A direction parallel to the first surface 100A and perpendicular to the X-axis direction is taken as a Y-axis direction. A direction perpendicular to the X-axis direction and the Y-axis direction is taken as a Z-axis direction. The first surface 100A is perpendicular to the Z-axis direction. For example, in the specification, a direction along the Y-axis is taken as a first direction Y; a direction along the X-axis is taken as a second direction X; and a direction along the Z-axis is taken as a third direction Z.

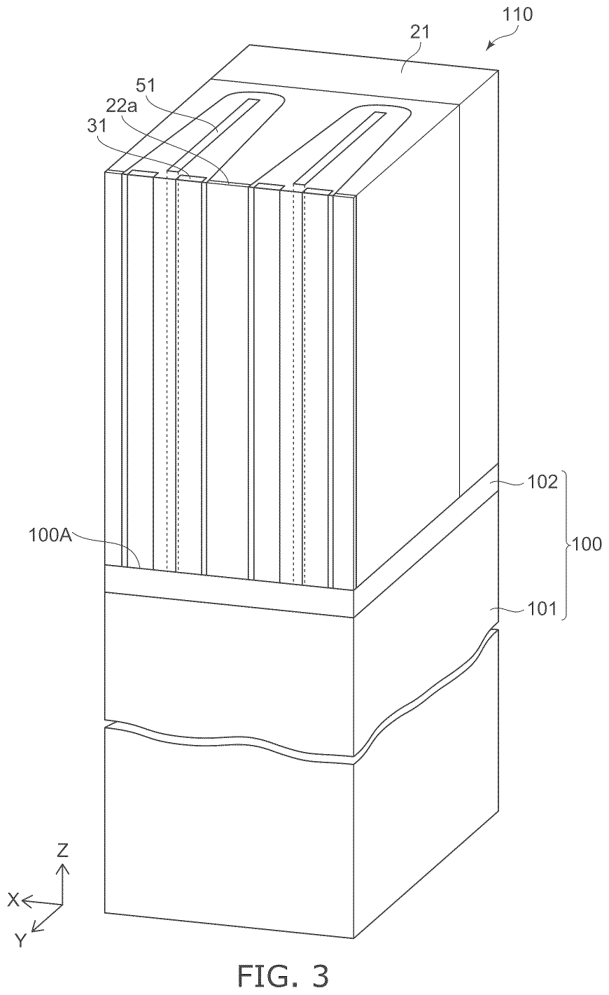

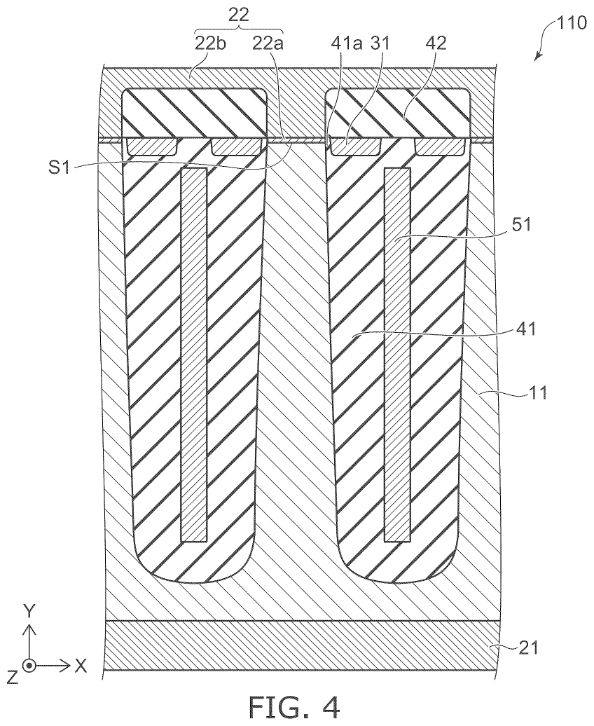

The major element 110 will now be described with reference to FIGS. 2 to 5B. FIG. 3 illustrates a state in which a second conductive part 22b and a second insulating member 42 are removed.

The support body 100 includes a substrate 101. For example, a silicon substrate can be used as the substrate 101. The major element 110 includes a first semiconductor layer 11 located on the substrate 101 in the third direction Z. The support body 100 may further include an insulating layer 102 located between the substrate 101 and the first semiconductor layer 11 in the third direction Z. In the example, the upper surface of the insulating layer 102 is used as the first surface 100A of the support body 100. For example, a silicon oxide layer can be used as the insulating layer 102.

The conductivity type of the first semiconductor layer 11 is a first conductivity type. The first conductivity type is one of an n- or p-type. Hereinbelow, the first conductivity type is the n-type. The first semiconductor layer 11 is, for example, a silicon layer. The first semiconductor layer 11 may be a silicon carbide layer or a gallium nitride layer.

The major element 110 further includes a first electrode 21 and a second electrode 22. The first electrode 21 and the second electrode 22 are positioned to be separated from each other in the first direction Y. The first semiconductor layer 11 is located between the first electrode 21 and the second electrode 22 in the first direction Y, and is electrically connected with the first and second electrodes 21 and 22. The first electrode 21, the second electrode 22, and the first semiconductor layer 11 extend in the third direction Z above the first surface 100A. “Above” is the direction from the substrate 101 toward the first semiconductor layer 11. “Above” is the direction from a second surface 101B toward the first surface 100A. “Below” is the opposite direction of “above”. “Above” and “below” are independent of the direction of gravity. By such a configuration, the density of the major elements 110 on the first surface 100A of the support body 100 can be increased, and, for example, the on-resistance per unit area can be reduced.

The first electrode 21 can include, for example, at least one selected from the group consisting of Al, Cu, Mo, W, Ta, Co, Ru, Ti, and Pt.

The second electrode 22 includes a first conductive part 22a and a second conductive part 22b. The first conductive part 22a contacts the first semiconductor layer 11. The first semiconductor layer 11 and the first conductive part 22a form a first Schottky junction S1. The first conductive part 22a is positioned between the first semiconductor layer 11 and the second conductive part 22b in the first direction Y. The second conductive part 22b is electrically connected with the first conductive part 22a.

The first conductive part 22a can include, for example, at least one selected from the group consisting of Ti, W, Mo, Ta, Zr, Al, Sn, V, Re, Os, Ir, Pt, Pd, Rh, Ru, Nb, Sr, and Hf. The second conductive part 22b can include, for example, at least one selected from the group consisting of Al, Cu, Mo, W, Ta, Co, Ru, Ti, and Pt.

The major element 110 further includes a first gate electrode 31. Multiple first gate electrodes 31 are arranged in the second direction X. The first gate electrode 31 faces the first Schottky junction S1 in the second direction X. For example, polycrystalline silicon can be used as the material of the first gate electrode 31. As shown in FIG. 3, the first gate electrode 31 extends in the third direction Z. By such a configuration, transistors can be arranged with high density on the first surface 100A of the support body 100; and the channel area per unit area can be increased. For example, the on-resistance can be reduced thereby. In the major element 110, a current does not flow through the support body 100; therefore, even when the thickness of the support body 100 in the third direction Z is increased to increase the mechanical strength, the on-resistance is not increased.

A potential that is higher than the potential of the second electrode 22 is applied to the first electrode 21; and a potential (e.g., the ground potential) that is lower than the potential of the first electrode 21 is applied to the second electrode 22. The first electrode 21 functions as a drain electrode; and the second electrode 22 functions as a source electrode. The n-type impurity concentration of the region of the first semiconductor layer 11 contacting the first electrode 21 may be greater than the n-type impurity concentration of the other regions. The contact resistance between the first electrode 21 and the first semiconductor layer 11 can be reduced thereby.

The potential of the first gate electrode 31 can control the thickness (the distance in the first direction Y) of the Schottky barrier of the first Schottky junction S1. When the Schottky barrier is thick, a current substantially does not flow between the second electrode 22 and the first semiconductor layer 11. The off-state is obtained thereby. In the off-state, a depletion layer can spread from the first Schottky junction S1 through the first semiconductor layer 11; and the breakdown voltage can be maintained.

By controlling the potential of the first gate electrode 31, the Schottky barrier can be thin, and, for example, a tunnel current flows between the second electrode 22 and the first semiconductor layer 11. An on-state is obtained by the flow of the tunnel current.

The major element 110 may further include a field plate electrode 51, a first insulating member 41, and the second insulating member 42.

The field plate electrode 51 is located inside a trench formed in the first semiconductor layer 11, and extends in the first and third directions Y and Z. For example, the field plate electrode 51 is electrically connected with the second electrode 22. The field plate electrode 51 can relax the electric field applied in the first direction Y to the first semiconductor layer 11, and can increase the breakdown voltage. For example, polycrystalline silicon can be used as the material of the field plate electrode 51.

The first insulating member 41 extends in the third direction Z, and is located between the first gate electrode 31 and the first semiconductor layer 11, between the field plate electrode 51 and the first semiconductor layer 11, between the first gate electrode 31 and the field plate electrode 51, and between the first gate electrodes 31 adjacent to each other in the second direction X. The first insulating member 41 includes a first gate insulating part 41a. The first gate insulating part 41a is located between the first gate electrode 31 and the first semiconductor layer 11, between the first gate electrode 31 and the first Schottky junction S1, and between the first gate electrode 31 and the first conductive part 22a. The first gate electrode 31 faces the first Schottky junction S1 in the second direction X via the first gate insulating part 41a. For example, silicon oxide can be used as the material of the first insulating member 41.

The second insulating member 42 extends in the third direction Z, and is located between the first gate electrode 31 and the second conductive part 22b and between the first insulating member 41 and the second conductive part 22b. For example, silicon oxide can be used as the material of the second insulating member 42.

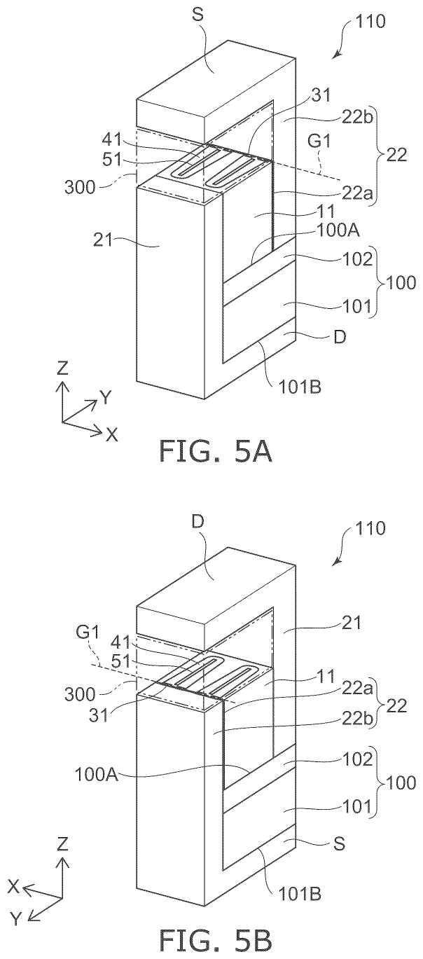

As shown in FIG. 5A, the substrate 101 includes the second surface 101B positioned at the side opposite to the first surface 100A in the third direction Z. An inter-layer insulating layer 300 (illustrated by a double dot-dash line) contacts the top of the first semiconductor layer 11. A first wiring part D that is electrically connected with the first electrode 21 is located at the second surface 101B of the substrate 101. The first electrode 21 can be electrically connected with an external circuit via the first wiring part D. A portion of the first wiring part D is positioned below the semiconductor device 1 and is exposed. The portion of the first wiring part D extends parallel to the first and second directions Y and X. In the third direction Z, the substrate 101 is positioned between the first wiring part D and the first semiconductor layer 11. A second wiring part S can be located above the first semiconductor layer 11, above the first gate electrode 31, and above the field plate electrode 51 with an inter-layer insulating layer interposed. The second wiring part S is electrically connected with the second conductive part 22b of the second electrode 22. The second electrode 22 can be electrically connected with an external circuit via the second wiring part S. A portion of the second wiring part S is positioned at the top of the semiconductor device 1 and is exposed. A portion of the second wiring part S extends parallel to the first and second directions Y and X. The inter-layer insulating layer 300 is positioned between the first semiconductor layer 11 and the portion of the second wiring part S. “Exposed” refers to being present at the surface of the semiconductor element, but not necessarily present at a surface of a resin, ceramic, or other package material. A first gate wiring part G1 that extends in the second direction X can be located on the multiple first gate electrodes 31 arranged in the second direction X; and the multiple first gate electrodes 31 can be electrically connected with the first gate wiring part G1. The first gate wiring part G1 is positioned inside the inter-layer insulating layer 300. The first gate wiring part G1 may be positioned above the semiconductor device 1 and may be exposed. For example, the semiconductor device 1 can be placed on an electrode of the external circuit so that the second wiring part S contacts the electrode. A wiring part of the semiconductor device 1 other than the second wiring part S is exposed at the top of the semiconductor device 1, and is connected with an external circuit by a technique such as wire bonding, etc. In the semiconductor device 1, the exposed area of the first and second wiring parts D and S, i.e., the contact area with the external circuit, i.e., the major current path, can be increased.

Or, as shown in FIG. 5B, the second wiring part S that is electrically connected with the second conductive part 22b of the second electrode 22 may be located at the second surface 101B of the substrate 101. The first wiring part D that is electrically connected with the first electrode 21 can be located above the first semiconductor layer 11, above the first gate electrode 31, and above the field plate electrode 51 in the third direction Z with an inter-layer insulating layer interposed. A portion of the first wiring part D is positioned at the top of the semiconductor device 1, and is exposed. The portion of the first wiring part D extends parallel to the first and second directions Y and X. A portion of the second wiring part S is positioned at the bottom of the semiconductor device 1, and is exposed. The portion of the second wiring part S extends parallel to the first and second directions Y and X.

As shown in FIG. 1, the area of the region in which the major element 110 is located is greater than the area of the region in which the control elements 120 are located. Multiple cell groups (first to fourth cell groups 71 to 74) are located in a region of the semiconductor device 1 in which the major element 110 is located. “Cell group” refers to the cell group of the major element 110 sharing the first semiconductor layer 11. In the first direction Y, the second cell group 72 is between the first cell group 71 and the fourth cell group 74; and the third cell group 73 is between the second cell group 72 and the fourth cell group 74. In each cell group, a plurality of the structure shown in FIGS. 2 to 4 above is repeatedly arranged in the second direction X.

The orientation from the first electrode 21 of the first cell group 71 toward the second electrode 22 of the first cell group 71 is the opposite of the orientation from the first electrode 21 of the second cell group 72 toward the second electrode 22 of the second cell group 72. The orientation from the first electrode 21 of the third cell group 73 toward the second electrode 22 of the third cell group 73 is the opposite of the orientation from the first electrode 21 of the fourth cell group 74 toward the second electrode 22 of the fourth cell group 74. The orientation from the first electrode 21 of the first cell group 71 toward the second electrode 22 of the first cell group 71 is the same as the orientation from the first electrode 21 of the third cell group 73 toward the second electrode 22 of the third cell group 73. The orientation from the first electrode 21 of the second cell group 72 toward the second electrode 22 of the second cell group 72 is the same as the orientation from the first electrode 21 of the fourth cell group 74 toward the second electrode 22 of the fourth cell group 74.

The first electrode 21 is shared by the second and third cell groups 72 and 73. The second electrode 22 is shared by the first and second cell groups 71 and 72. The second electrode 22 is shared by the third and fourth cell groups 73 and 74.

For example, the major element 110 can be included in a high-side switching element and a low-side switching element of a voltage converter.

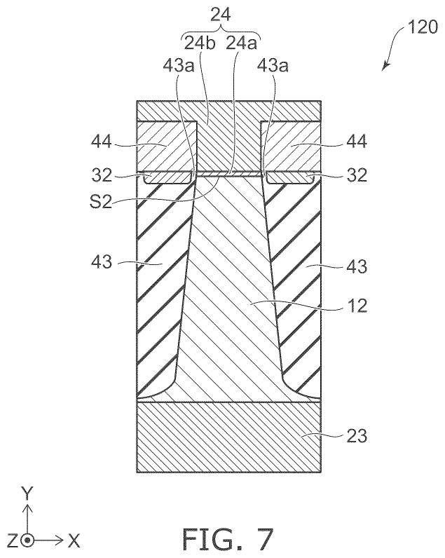

The control element 120 will now be described with reference to FIGS. 6 and 7.

For example, the control element 120 is located on the same substrate 101 as the major element 110; the fourth direction of the control element 120 is aligned with the first direction Y of the major element 110; the fifth direction of the control element 120 is aligned with the second direction X of the major element 110; and the sixth direction of the control element 120 is aligned with the third direction Z of the major element 110. The control element 120 is positioned to be separated from the major element 110 at the XY-plane. The control element 120 includes a second semiconductor layer 12 located on the substrate 101 in the third direction (the sixth direction) Z. The conductivity type of the second semiconductor layer 12 is the first conductivity type. The material of the second semiconductor layer 12 can be the same as the material of the first semiconductor layer 11 of the major element 110.

The control element 120 further includes a third electrode 23 and a fourth electrode 24. The third electrode 23 and the fourth electrode 24 are positioned to be separated from each other in one direction, e.g., the first direction (the fourth direction) Y, in the XY-plane. The second semiconductor layer 12 is located between the third electrode 23 and the fourth electrode 24 in the first direction (the fourth direction) Y, and is electrically connected with the third and fourth electrodes 23 and 24. The third electrode 23, the fourth electrode 24, and the second semiconductor layer 12 extend in the third direction (the sixth direction) Z above the first surface 100A of the support body 100.

The fourth electrode 24 includes a third conductive part 24a and a fourth conductive part 24b. The third conductive part 24a contacts the second semiconductor layer 12. The second semiconductor layer 12 and the third conductive part 24a form a second Schottky junction S2. The third conductive part 24a is positioned between the second semiconductor layer 12 and the fourth conductive part 24b in the first direction (the fourth direction) Y. The fourth conductive part 24b is electrically connected with the third conductive part 24a.

The material of the third electrode 23 can be the same as the material of the first electrode 21 of the major element 110. The material of the third conductive part 24a can be the same as the material of the first conductive part 22a of the major element 110. The material of the fourth conductive part 24b can be the same as the material of the second conductive part 22b of the major element 110.

The control element 120 further includes a second gate electrode 32. Multiple second gate electrodes 32 are arranged in one direction, e.g., the second direction (the fifth direction) X, in the XY-plane. The second gate electrode 32 faces the second Schottky junction S2 in the second direction (the fifth direction) X. The second gate electrode 32 extends in the third direction (the sixth direction) Z. The material of the second gate electrode 32 can be the same as the material of the first gate electrode 31 of the major element 110.

The potential of the second gate electrode 32 can control the thickness (the distance in the first direction (the fourth direction) Y) of the Schottky barrier of the second Schottky junction S2. When the Schottky barrier is thick, a current substantially does not flow between the fourth electrode 24 and the second semiconductor layer 12. The off-state is obtained thereby. By controlling the potential of the second gate electrode 32, the Schottky barrier can be thin, and, for example, a tunnel current flows between the fourth electrode 24 and the second semiconductor layer 12. The on-state is obtained by the flow of the tunnel current.

The control element 120 may further include a third insulating member 43 and a fourth insulating member 44.

The third insulating member 43 is located between the second gate electrode 32 and the second semiconductor layer 12 and extends in the third direction (the sixth direction) Z. As shown in FIG. 7, the third insulating member 43 includes a second gate insulating part 43a. The second gate insulating part 43a is located between the second gate electrode 32 and the second semiconductor layer 12, between the second gate electrode 32 and the second Schottky junction S2, and between the second gate electrode 32 and the third conductive part 24a. The second gate electrode 32 faces the second Schottky junction S2 in the second direction (the fifth direction) X via the second gate insulating part 43a. The material of the third insulating member 43 can be the same as the material of the first insulating member 41 of the major element 110.

The fourth insulating member 44 extends in the third direction (the sixth direction) Z, and is located between the second gate electrode 32 and the fourth conductive part 24b and between the third insulating member 43 and the fourth conductive part 24b. The material of the fourth insulating member 44 can be the same as the material of the second insulating member 42 of the major element 110.

According to the embodiment, the major element 110 and the control element 120 can be formed using the same process by only changing the mask pattern between the major element 110 and the control element 120 when etching and forming films for forming the components of the major element 110 and the control element 120. For example, the first semiconductor layer 11 and the second semiconductor layer 12 can be formed on the same substrate 101; and the major element 110 and the control element 120 can be formed as-is as one chip. As a result, a power semiconductor device in which the control element 120 is inexpensively embedded can be made in one chip. When the major element 110 and the control element 120 are made in one chip, the parasitic inductance of the wiring parts electrically connecting between the major element 110 and the control element 120 can be reduced.

As shown in FIG. 1, a fifth insulating member 60 can be located between the major element 110 and the control element 120 on the substrate 101. The fifth insulating member 60 also can be located between the multiple control elements 120. For example, silicon oxide can be used as the material of the fifth insulating member 60.

Or, after forming the first semiconductor layer 11 and the second semiconductor layer 12 on the same substrate 101, the chip of the major element 110 and the chip of the control element 120 may be separated. In such a case, the chip of the major element 110 and the chip of the control element 120 can be mounted on the same wiring substrate and packaged. In such a case, the wiring substrate can be included as the support body supporting the major element 110 and the control element 120.

The third electrode 23 of the control element 120 can be electrically connected with an external circuit via a third wiring part located above the second semiconductor layer 12 in the third direction (the sixth direction) Z. The fourth electrode 24 can be electrically connected with the external circuit via a fourth wiring part located above the second semiconductor layer 12 in the third direction (the sixth direction) Z. The second gate electrode 32 can be electrically connected with a second gate wiring part G2 that is located on the second gate electrode 32 and extends in the second direction (the fifth direction) X. The third wiring part, the fourth wiring part, and the second gate wiring part G2 can be connected with the external circuit by being exposed outside the semiconductor device 1 at the top of the semiconductor device 1.

An inter-layer insulating layer is located on the second semiconductor layer 12. The third wiring part, the fourth wiring part, and the second gate wiring part G2 are located inside the inter-layer insulating layer. The third wiring part, the fourth wiring part, and the second gate wiring part G2 can be connected with the wiring parts of the major element 110 and the wiring parts of the other control element 120 inside the inter-layer insulating layer. Compared to when wire bonding is used for the connections, for example, the parasitic inductance can be reduced. The area of the electrode pads, i.e., the wiring parts, of the major element 110 can be increased.

As a result, a leakage current between the first wiring part D or the second wiring part S of the major element 110 described above and the major electrodes (the third electrode 23 and the fourth electrode 24) of the control element 120 can be suppressed.

The voltage that is applied between the first electrode 21 and the second electrode 22 of the major element 110 is greater than the voltage applied between the third electrode 23 and the fourth electrode 24 of the control element 120. For example, the voltage that is applied between the first electrode 21 and the second electrode 22 of the major element 110 is not less than 100 V; and the voltage that is applied between the third electrode 23 and the fourth electrode 24 of the control element 120 is about several V. Therefore, because the breakdown voltage of the major element 110 is high, it is favorable for the thickness in the first direction Y of the first semiconductor layer 11 of the major element 110 to be greater than the thickness in the first direction Y of the second semiconductor layer 12 of the control element 120.

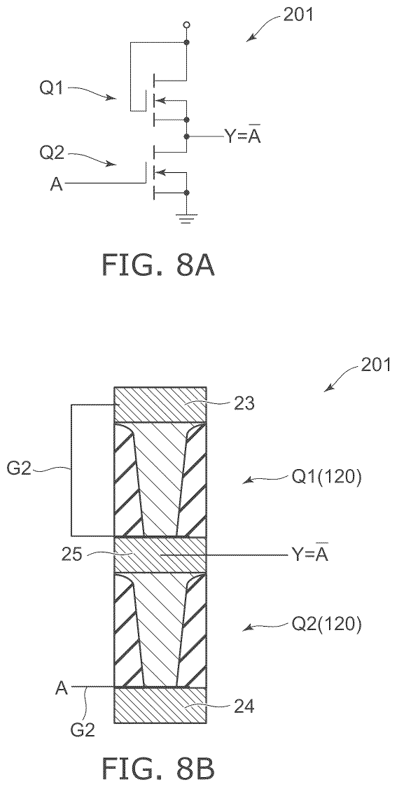

At least one of the third electrode 23 or the fourth electrode 24 of the control element 120 is electrically connected with the first gate electrode 31 of the major element 110. The control element 120 forms a control circuit that controls the potential of the first gate electrode 31 of the major element 110. Examples of the control circuit in which multiple control elements 120 are formed will now be described with reference to FIGS. 8A to 11B.

FIGS. 8A and 8B show an example in which the multiple control elements 120 form a NOT circuit 201. An example is described in which the multiple control elements 120 each are MOSFETs in which an n-type semiconductor layer and an electrode form a Schottky junction. The multiple control elements 120 each may be MOSFETs in which a MOS gate electrode is included in an n-p-n junction or p-n-p junction semiconductor structure. The configuration of a logic circuit in which a MOSFET of only one polarity, e.g., an n-type MOSFET, is used will now be described as an example. The logic circuit can be replaced with a circuit that includes a CMOS including both an n-type MOSFET and a p-type MOSFET. The NOT circuit 201 includes a first control element Q1 (120) and a second control element Q2 (120). The second electrode of the first control element Q1 and the first electrode of the second control element Q2 are a common electrode 25 that is shared by the first and second control elements Q1 and Q2. The second gate wiring part G2 that is electrically connected with the second gate electrode 32 of the first control element Q1 is electrically connected with the first electrode 21 of the first control element Q1. A power supply voltage is applied to the first electrode 21 of the first control element Q1; and the second electrode 22 of the second control element Q2 is grounded. A signal “A” is input to the second gate wiring part G2 electrically connected with the second gate electrode 32 of the second control element Q2; and a signal “Y” that is the inverse of the signal “A” is output to the common electrode 25 (the output terminal).

When the circuit is configured by connecting the third electrode 23 or the fourth electrode 24 of one control element Q1 (120) and the third electrode 23 or the fourth electrode 24 of another control element Q2 (120), the third electrode 23 or the fourth electrode 24 that are connected are a continuous body. In such a case, the direction from the third electrode 23 toward the fourth electrode 24 of the one control element Q1 (120) is aligned with the direction from the third electrode 23 toward the fourth electrode 24 of the other control element Q2 (120). The area of the wiring parts connecting the control elements 120 to each other can be reduced. The placement area of the control element 120 itself can be reduced. The area that is occupied by the control elements 120 on the first surface 100A of the support body 100 can be reduced, and the channel area of the major element 110 per unit area can be increased.

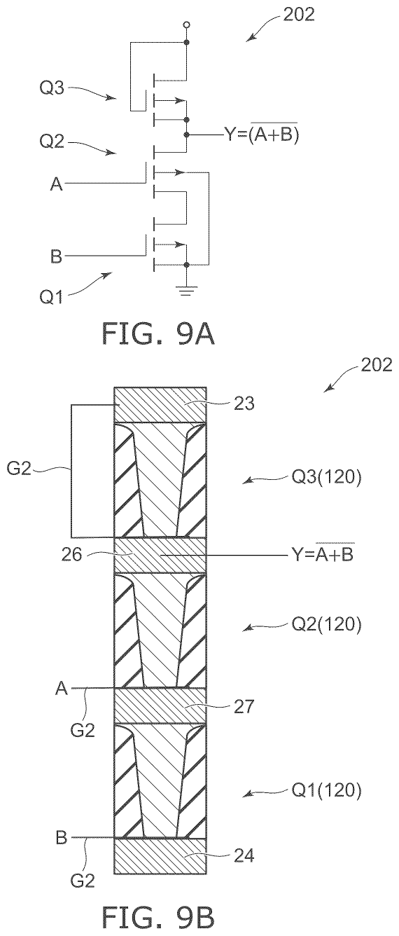

FIGS. 9A and 9B show an example in which the multiple control elements 120 form a NOR circuit 202. The NOR circuit 202 includes the first control element Q1 (120), the second control element Q2 (120), and a third control element Q3 (120). The second electrode of the third control element Q3 and the first electrode of the second control element Q2 are a first common electrode 26 shared by the third and second control elements Q3 and Q2. The second electrode of the second control element Q2 and the first electrode of the first control element Q1 are a second common electrode 27 shared by the second and first control elements Q2 and Q1. The second gate wiring part G2 that is electrically connected with the second gate electrode 32 of the third control element Q3 is electrically connected with the first electrode 21 of the third control element Q3. A power supply voltage is applied to the first electrode 21 of the third control element Q3; and the second electrode 22 of the first control element Q1 is grounded. The signal “A” is input to the second gate wiring part G2 electrically connected with the second gate electrode 32 of the second control element Q2; a signal “B” is input to the second gate wiring part G2 electrically connected with the second gate electrode 32 of the first control element Q1; and the signal “Y” that is the inverse of the signal “A+B” is output to the first common electrode 26 (the output terminal).

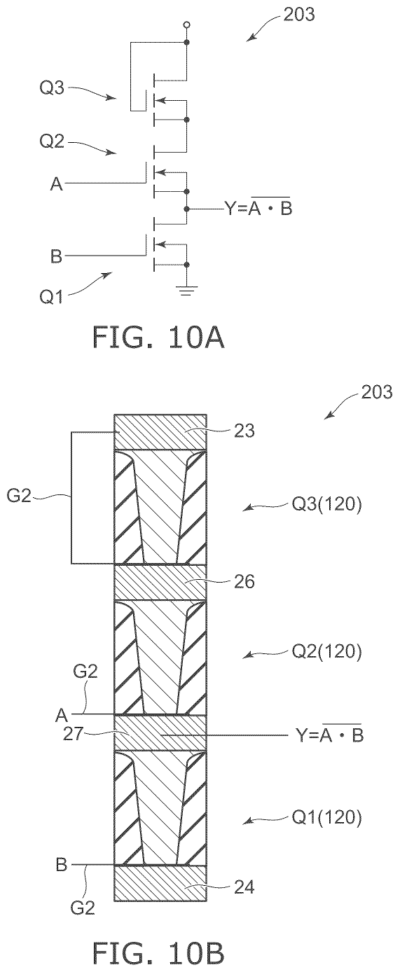

FIGS. 10A and 10B show an example in which the multiple control elements 120 form a NAND circuit 203. The NAND circuit 203 includes the first control element Q1 (120), the second control element Q2 (120), and the third control element Q3 (120). The second electrode of the third control element Q3 and the first electrode of the second control element Q2 are the first common electrode 26 shared by the third and second control elements Q3 and Q2. The second electrode of the second control element Q2 and the first electrode of the first control element Q1 are the second common electrode 27 shared by the second and first control elements Q2 and Q1. The second gate wiring part G2 that is electrically connected with the second gate electrode 32 of the third control element Q3 is electrically connected with the first electrode 21 of the third control element Q3. A power supply voltage is applied to the first electrode 21 of the third control element Q3; and the second electrode 22 of the first control element Q1 is grounded. The signal “A” is input to the second gate wiring part G2 electrically connected with the second gate electrode 32 of the second control element Q2; the signal “B” is input to the second gate wiring part G2 electrically connected with the second gate electrode 32 of the first control element Q1; and the signal “Y” that is the inverse of the signal “A·B” is output to the second common electrode 27 (the output terminal).

The NOT circuit 201, the NOR circuit 202, and the NAND circuit 203 can be made individually by modifying only the mask pattern.

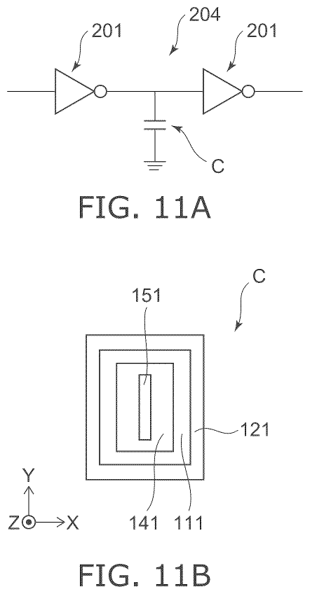

As shown in FIGS. 11A and 11B, the multiple control elements 120 can form a delay circuit 204. The delay circuit 204 includes two NOT circuits 201 connected in series, and a capacitor C connected between ground and the connection node of the two NOT circuits 201.

The capacitor C includes a fifth electrode 121, a sixth electrode 151, a third semiconductor layer 111, and a sixth insulating member 141. The fifth electrode 121, the sixth electrode 151, the third semiconductor layer 111, and the sixth insulating member 141 extend in the third direction Z on the first surface 100A of the support body 100. The fifth electrode 121 and the sixth electrode 151 are positioned to be separated in the first and second directions Y and X with the third semiconductor layer 111 and the sixth insulating member 141 interposed. For example, in the XY-plane, the fifth electrode 121 continuously surrounds the third semiconductor layer 111; the third semiconductor layer 111 continuously surrounds the sixth insulating member 141; and the sixth insulating member 141 continuously surrounds the sixth electrode 151.

The fifth electrode 121, the sixth electrode 151, the third semiconductor layer 111, and the sixth insulating member 141 can be formed by the same processes as the major element 110 and the control element 120 described above by modifying only the mask pattern. For example, the fifth electrode 121 can be formed by the same processes as one of the first to fourth electrodes 21 to 24. The sixth electrode 151 can be formed by the same processes as the field plate electrode 51. The third semiconductor layer 111 can be formed by the same processes as the first and second semiconductor layers 11 and 12. The sixth insulating member 141 can be formed by the same processes as the first and third insulating members 41 and 43.

While certain embodiments of the inventions have been described, these embodiments have been presented by way of example only, and are not intended to limit the scope of the inventions. These novel embodiments may be embodied in a variety of other forms; and various omissions, substitutions, and changes may be made without departing from the spirit of the inventions. Such embodiments and their modifications are within the scope and spirit of the inventions, and are within the scope of the inventions described in the claims and their equivalents.

What is claimed is:

1. A semiconductor device, comprising:
a support body including a first surface;
a major element located on the support body; and
a control element located on the support body, the control element controlling the major element,
the major element including
a first electrode,
a second electrode positioned to be separated from the first electrode in a first direction, the first direction being along the first surface,
a first semiconductor layer located between the first electrode and the second electrode in the first direction, the first semiconductor layer forming a first Schottky junction with the second electrode, and
a first gate electrode facing the first Schottky junction in a second direction, the second direction being along the first surface and crossing the first direction,
the control element including
a third electrode,
a fourth electrode positioned to be separated from the third electrode in a fourth direction, the fourth direction being along the first surface,
a second semiconductor layer located between the third electrode and the fourth electrode in the fourth direction, the second semiconductor layer forming a second Schottky junction with the fourth electrode, and
a second gate electrode facing the second Schottky junction in a fifth direction, the fifth direction being along the first surface and crossing the fourth direction.

2. The device according to claim 1, wherein
the support body includes a substrate, and
the first semiconductor layer and the second semiconductor layer each are located on the substrate.

3. The device according to claim 2, wherein
the substrate includes a second surface positioned at a side opposite to the first surface in a third direction crossing the first and second directions, and
the third and fourth electrodes of the control element are positioned on the first surface but not positioned at the second surface.

4. The device according to claim 1, wherein
a thickness in the first direction of the first semiconductor layer is greater than a thickness in the fourth direction of the second semiconductor layer.

5. The device according to claim 1, wherein
a plurality of the control elements forms a NOT circuit.

6. The device according to claim 1, wherein
a plurality of the control elements forms a NOR circuit.

7. The device according to claim 1, wherein
a plurality of the control elements forms a NAND circuit.

8. The device according to claim 1, wherein
at least one of the third electrode or the fourth electrode of the control element is electrically connected with the first gate electrode of the major element.

9. The device according to claim 3, wherein
the major element further includes an inter-layer insulating layer, and
the inter-layer insulating layer contacts a top of the first semiconductor layer in the third direction.

10. The device according to claim 9, wherein
the major element includes a first gate wiring part inside the inter-layer insulating layer, and
the first gate wiring part is connected to the first gate electrode.

11. The device according to claim 3, comprising:
a plurality of the control elements,
the plurality of control elements including at least a first control element and a second control element,
the second control element being positioned in the fourth direction with respect to the first control element,
the fourth electrode of the first control element and the third electrode of the second control element being connected as a continuous body.

12. The device according to claim 11, wherein
the second gate electrode of the first control element is connected to the third electrode of the first control element.
